(19) United States
(12) Patent Application Publication
(10) Pub. No.: US 2011/0260340 A1
(43) Pub. Date: Oct. 27, 2011

(54) CIRCUIT BOARD STRUCTURE, PACKAGING STRUCTURE AND METHOD FOR MAKING THE SAME

(76) Inventor: Lee-Sheng Yen, Taoyuan County (TW)

(21) Appl. No.: 12/814,513

(22) Filed: Jun. 14, 2010

(30) Foreign Application Priority Data
Apr. 26, 2010 (TW) 099113042

(51) Int. Cl. H01L 23/48; H01L 21/56; H05K 1/11

(52) U.S. Cl. 257/782; 174/261; 438/124; 257/E23.01; 257/E21.502

(57) ABSTRACT

A method for making a circuit board structure is disclosed. First, a substrate is provided. The substrate includes a carrier, a copper film and a release film disposed between them. Next, the copper film is patterned to form a connecting pattern and a die pad. Later, a passivation layer is formed to cover the connecting pattern and the die pad.

### BACKGROUND OF THE INVENTION

1. Field of the Invention

The present invention generally relates to a method for making a circuit board structure, the circuit board structure and the package structure obtained therefrom. In particular, the present invention is directed to a method for making a circuit board structure and a package structure by means of a carrier and a copper film with a release film attached thereon.

2. Description of the Prior Art

A circuit board is an essential component of an electronic device. With the trend of always scaling down the size of the electronic devices, various carrier structures are therefore proposed to support the die. Some pins extend outwards to connect other circuits surrounding the circuit board to form proper electrical connections.

As far as the current technology is concerned, a circuit structure called “lead frame” is conventionally known. FIGS. 1-4 illustrate a method for making a traditional lead frame. Please refer to FIG. 1, first a metal substrate 101 is provided. Second, please refer to FIG. 2, the metal substrate 101 is patterned to form a circuit pattern 110 and a die pad 111 which correspond to a die (not shown). Later, via holes 122 are formed, pins 120 are connected to the metal substrate 101 as well as pins 120 and the die pad 111 are plated with silver. Next, please refer to FIG. 3, the die 130 is attached to the die pad 111 then followed by a wire bonding step and a tin plating step. Afterwards, please refer to FIG. 4, the pins are shaped to obtained a package structure 102. The data in the die is connected with the outer circuits by the pins 120.

However, as the data processed by the die increases and the speed for processing needs to be higher, the lead frame as illustrated cannot provide more pins 120 to meet the demands because the space around the die is so limited. In such a way, the application of the traditional lead frame 102 as a result is restricted.

FIG. 5 illustrates another carrier structure 201 for supporting dies. In the carrier structure 201, the circuit patterns 220 are respectively disposed on both opposite sides of the substrate 210. In addition, the solder mask layer 230 is selectively disposed on both opposite sides of the substrate 210 to properly protect the circuit pattern 220. Apart from this, some of the circuit pattern 220 is exposed. In the carrier structure 201, independent solder mask layers 231/232 need to be formed on both opposite sides of the substrate 210. The patterns of the solder mask layers 231/232 are usually distinctively different so that they can cope with different demands, such as location, of die pads (not shown) and different solder balls (not shown).

After the carrier structure 201 for supporting dies as illustrated in FIG. 5 undergoes suitable packaging steps, the package structure 202 as illustrated in FIG. 6 is obtained. In addition to the substrate 210, the circuit pattern 220, the solder mask layer 230, and the solder mask layers 231/232 as illustrated in FIG. 5, there are extra die pad 221, die 240, bonding wire 250, sealant material 260 and solder balls 270 in the package structure 202 as illustrated in FIG. 6 due to the subsequent packaging steps.

The die 240 is disposed on the die pad 221 within the circuit pattern 220 and surrounded by the solder mask layer 231 at the same time as well as electrically connected to other parts of the circuit pattern 220 by means of the bonding wires 250. The sealant material 260 completely covers the die pad 221, the die 240, the bonding wire 250 and partially covers the substrate 210 and the solder mask layer 230. The solder balls 270 are surrounded by the solder mask layer 232. In both the carrier structure 201 for supporting dies as illustrated in FIG. 5 and the package structure 202 as illustrated in FIG. 6, the solder mask layers 231/232 are independently disposed on two opposite sides of the substrate 210 and extend to the margins of the substrate 210.

In the light of the above-mentioned carrier structures, the package structures and the conventional methods for making lead frames are yet perfect, other novel carrier structures, package structures and the fabrication methods are still needed to provide a much simpler structure and to be free from being restricted conventionally.

### SUMMARY OF THE INVENTION

The present invention hence proposes a novel circuit board structure, a package structure and the fabrication methods thereof. The circuit board structure and the package structure of the present invention employ an area array design to decrease the packaging size by increasing the design space. Besides, the release film of the present invention facilitates the release of the carrier and the copper film.

The present invention in a first aspect proposes a method for making a circuit board structure. Firstly, a substrate is provided. The substrate includes a carrier, a copper film and a release film disposed between the carrier and the copper film. Second, the copper film is patterned to form a connecting pattern and a die pad. Afterwards, a first passivation layer is formed to respectively cover the connecting pattern and the die pad to form a circuit board structure.

In one embodiment of the present invention, the release film is first applied onto the copper film then the release film with the copper film is attached onto the carrier to form the substrate. In another embodiment of the present invention, the release film is first applied onto the carrier then the release film with the carrier is attached onto the copper film to form the substrate. In a further embodiment of the present invention, a package is formed on the carrier. In still another embodiment of the present invention, the release film along with the carrier is removed to expose a die pad and a connecting pattern to obtain a package structure.

The present invention in a second aspect proposes a circuit board structure. The circuit board structure of the present invention includes a carrier, a release film, a connecting pattern, a die pad and a passivation layer. The release film is attached to the carrier and the connecting pattern is disposed on the release film and in direct contact with the release film. The die pad is disposed on the release film and in direct contact with the release film. The passivation layer respectively covers the connecting pattern and the die pad.

The present invention in a third aspect proposes a package structure. The package structure includes a carrier, a release film, a sealant material, a connecting pattern, a die pad, a passivation layer, a die and a bonding wire. The release film is attached to the carrier and the sealant material covers the release film. The connecting pattern and the die pad are together disposed in the sealant material. The passivation layer is completely disposed in the sealant material and covers the connecting pattern and the die pad. The die is also completely disposed in the sealant material and disposed on the die pad. The bonding wire is completely disposed in the sealant material and selectively electrically connected to the die and the connecting pattern.

The present invention in a fourth aspect proposes another package structure. The package structure of the present invention includes a sealant material, a connecting pattern, a die pad, a passivation layer, a die and a bonding wire. Both the die pad and the connecting pattern are disposed in the sealant material. The passivation layer is completely disposed in the sealant material and covers the connecting pattern and the die pad. The die is also completely disposed in the sealant material and disposed on the die pad. The bonding wire is completely disposed in the sealant material and selectively electrically connected to the die and the connecting pattern.

The present invention in a fifth aspect proposes another package structure. The package structure of the present invention includes a sealant material, a connecting pattern, a die pad, a first passivation layer, a second passivation layer, a die and a bonding wire. Both the die pad and the connecting pattern are disposed in the sealant material. The first passivation layer is completely disposed in the sealant material and covers the connecting pattern and the die pad. The second passivation layer is disposed outside the sealant material and covers the connecting pattern and the die pad. The die is also completely disposed in the sealant material and disposed on the die pad. The bonding wire is completely disposed in the sealant material and selectively electrically connected to the die and the connecting pattern.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 illustrate a method for making a traditional lead frame.

FIG. 5 illustrates a traditional carrier structure for supporting dies.

FIG. 6 illustrates a traditional package structure.

FIGS. 7-8 illustrate the method for making a circuit board structure of the present invention.

FIG. 9 illustrates a circuit board structure proposed by the present invention.

FIG. 10 illustrates an extension method for making the pre-package structure of the present invention.

FIG. 11 illustrates an extension method for making another pre-package structure of the present invention.

FIG. 12 illustrates the package structure of the present invention.

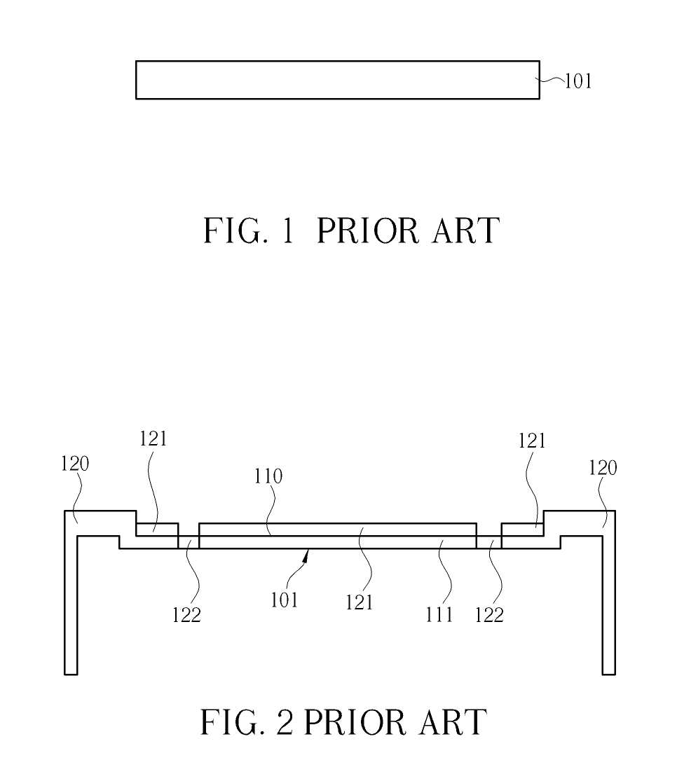

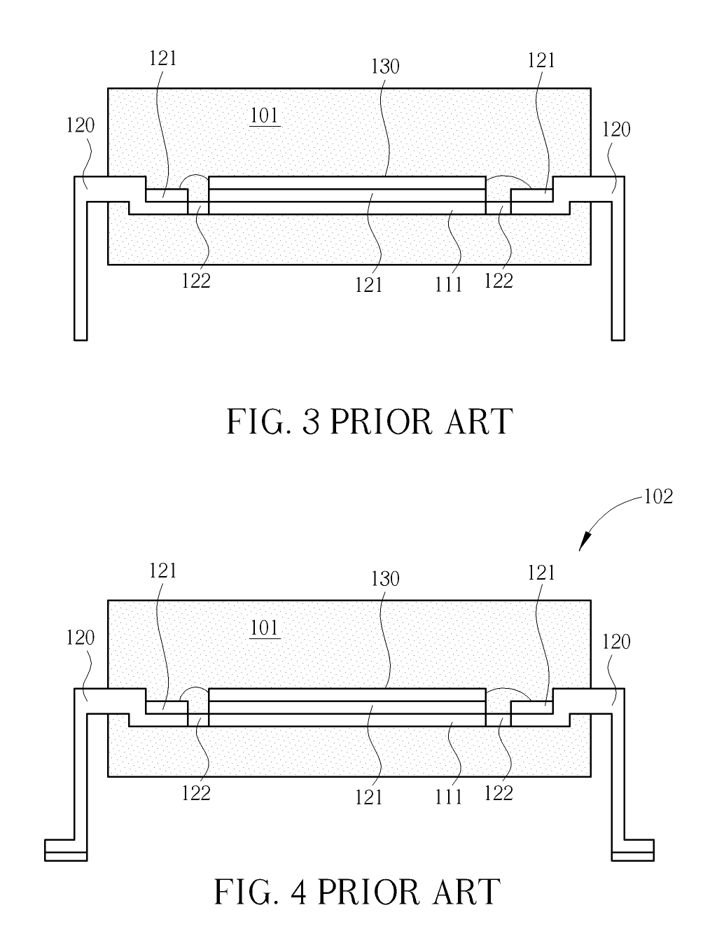

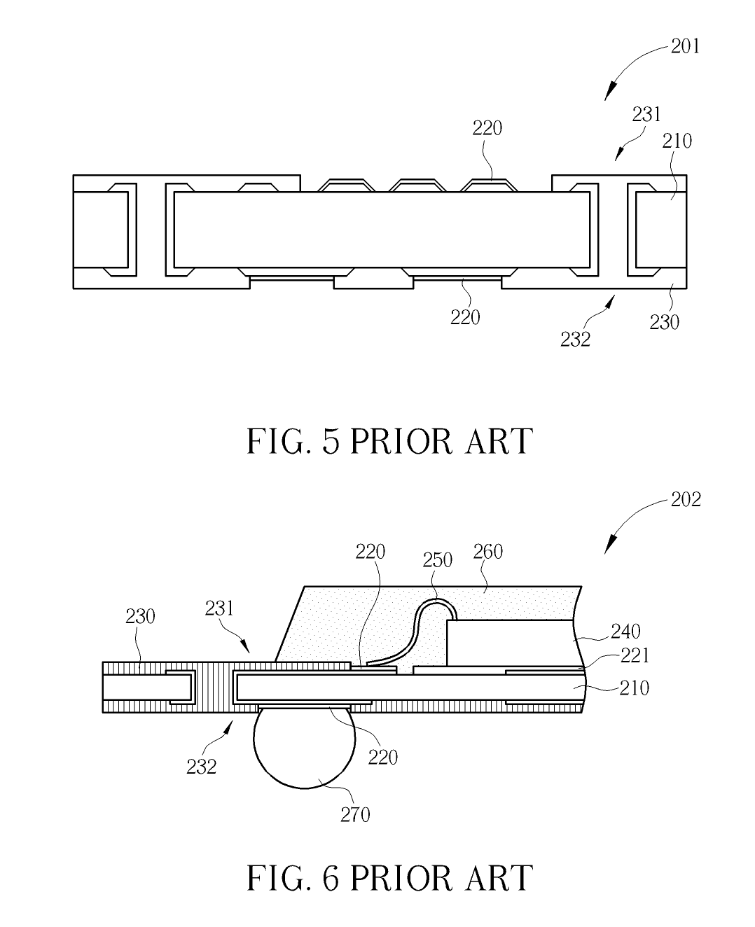

### DETAILED DESCRIPTION

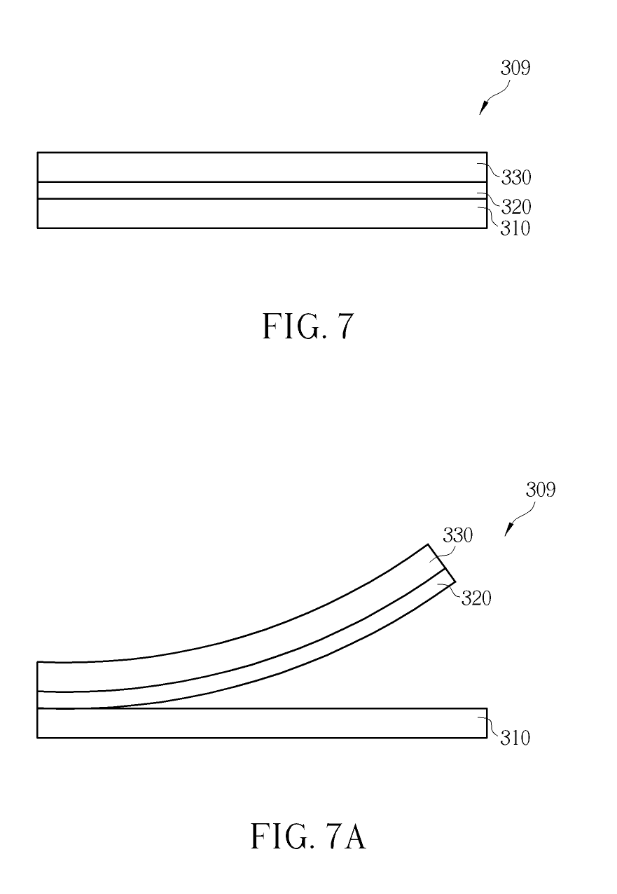

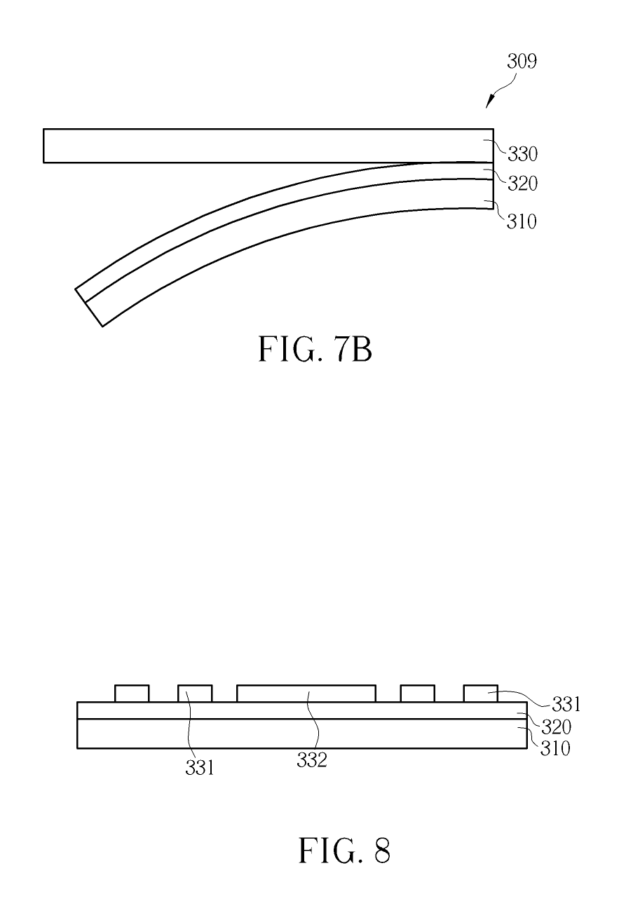

The present invention in a first aspect provides a method for making a circuit board structure. FIGS. 7-8 illustrate the method for making a circuit board structure of the present invention. Please refer to FIG. 7, first a substrate 309 is provided. The substrate 309 includes a carrier 310, a release film 320 and a copper film 330. The release film 320 is disposed between the carrier 310 and the copper film 330. The carrier 310 may be any suitable material, such as polyethylene terephthalate (PET), polycarbonate (PC), polymethylmethacrylate (PMMA) or a copperless substrate. The release film 320 may be a plastic and sticky material and has better adhesion to the carrier 310. The release film 320 accordingly adheres to one side of the carrier 310 by means of the adhesion. The substrate 309 may have a thickness of about 150 μm-400 μm, preferably 265 μm.

The carrier 310, the release film 320 and the copper film 330 in the substrate 309 may optionally have different processing steps. For example, as shown in FIG. 7A, in one embodiment of the present invention the release film 320 is first applied onto the copper film 330 before the release film 320 with the copper film 330 is attached onto the carrier 310 to form the substrate 309. In another embodiment of the present invention as shown in FIG. 7B, the release film 320 with the carrier 310 is later attached onto the copper film 330 to form the substrate 309 after the release film 320 is first applied onto the carrier 310. The release film 320 is always sandwiched between the copper film 330 and the carrier 310. At least one of a screen printing and a roller may be used to apply the release film 320 onto the copper film 330.

Second, please refer to FIG. 8. Because one side of the copper film 330 is still exposed, the copper film 330 will have a pattern such as a connecting pattern 331 and a die pad 332 once the copper film 330 is suitably patterned. The copper film 330 may be patterned by a wet film method or by a dry film method. The connecting pattern 331 and the die pad 332 each have different functions. For example, the die pad 332 may be useful for supporting a die (not shown). As to the connecting pattern 331, it may serve as the connecting pad of the die (not shown).

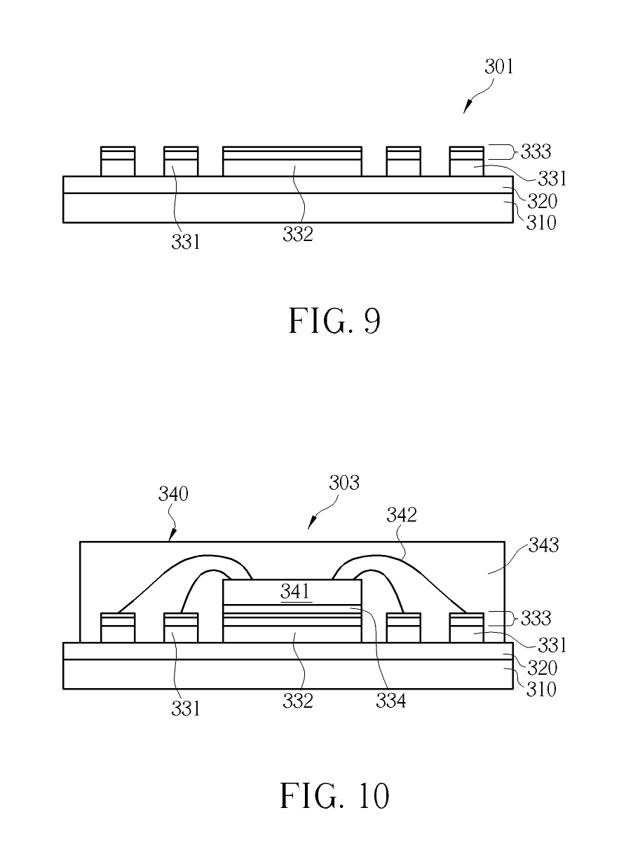

Afterwards, as shown in FIG. 9 a first passivation layer 333 should be formed on the surface of the copper film 330 to protect the fragile copper film 330. Because there are the connecting pattern 331 and the die pad 332 of different functions on the patterned copper film 330, the first passivation layer 333 covers the connecting pattern 331 and the die pad 332, too. A method such as an electroplating step may be used to form the first passivation layer 333 on the surface of the copper film 330. The first passivation layer 333 may be a composite material layer. For instance, the first passivation layer 333 may include at least one of Ni, Ag and Au, to form a Ni/Au protective layer.

After the aforesaid steps, the laminated carrier 310, release film 320 and copper film 330 together form a novel circuit board structure 301. Please refer to FIG. 9, illustrating the circuit board structure 301 proposed by the present invention. The circuit board structure 301 of the present invention includes the carrier 310, the release film 320, a connecting pattern 331, a die pad 332 and a first passivation layer 333. The release film 320 is attached to the carrier 310. The connecting pattern 331 and the die pad 332 are respectively disposed on the release film 320 and in direct contact with the release film 320. The first passivation layer 333 respectively covers the connecting pattern 331 as well as the die pad 332.

The carrier 310 may be any suitable material, such as polyethylene terephthalate (PET), polycarbonate (PC), polymethylmethacrylate (PMMA) and a copperless substrate. The release film 320 may be a plastic and sticky material and has better adhesion to the carrier 310. The release film 320 accordingly adheres to one side of the carrier 310 by means of the adhesion. The first passivation layer 333 may be a composite material layer. For instance, the first passivation layer 333 may include at least one of Ni, Ag and Au, to form a Ni/Au protective layer.

In another embodiment of the present invention, the circuit board structure 301 as illustrated in FIG. 9 may further become a pre-package structure 303 after a pre-package step. FIG. 10 illustrates an extension method for making the pre-package structure of the present invention. Please refer to FIG. 10, a package 340 may be further formed on the release film 320 of the circuit board structure 301 as illustrated in FIG. 9. For example, the die 341 is first adhered to the die pad 332. For example, a silver paste 334 or a thermal-dissipating material (not shown) is used to attach the die 341 onto the die pad 332. Then, bonding wires 342, such as copper wires, silver wires, gold wires or gold-plated copper wires, are used to optionally connect the die 341 to part of the connecting pattern 331 electrically. After the electrical connection is completed, a sealant material 343, such as an epoxy resin, may be employed to hermetically seal the die 341 and the bonding wires 342 to keep the die 341 and the bonding wires 342 from the atmosphere, such as humidity.

After a package 340 formed on the release film 320 in the circuit board structure 301 as illustrated in FIG. 9, a pre-package structure 303 is obtained, as shown in FIG. 10. The pre-package structure 303 includes a carrier 310, a release film 320, a connecting pattern 331, a die pad 332, a passivation layer 333, a die 341, a bonding wire 342 and a sealant material 343. The release film 320 is attached to the carrier 310 and the sealant material 342 covers the release film 320. The die pad 332 and the connecting pattern 331 are together disposed in the sealant material 343. The passivation layer 333 is completely disposed in the sealant material 343 and covers the connecting pattern 331 and the die pad 332. The die 341 is disposed on the die pad 332 and also completely disposed in the sealant material 343. The bonding wire 342 is completely disposed in the sealant material 343 and selectively electrically connected to the die 341 and the connecting pattern 331.

In a further embodiment of the present invention, the pre-package structure 303 as illustrated in FIG. 10 may further become another pre-package structure 305 after another step. FIG. 11 illustrates an extension method for making another pre-package structure of the present invention. Please refer to FIG. 11, another pre-package structure 305 is obtained after the carrier 310 and the release film 320 are removed at the same time or separately from the pre-package structure 303 as illustrated in FIG. 10. The pre-package structure 305 includes a connecting pattern 331, a die pad 332, a passivation layer 333, a die 341, a bonding wire 342 and a sealant material 343. The connecting pattern 331, the die pad 332, the passivation layer 333, the die 341 and the bonding wire 342 are all disposed in the sealant material 343. The passivation layer 333 covers the connecting pattern 331 and the die pad 332. The die 341 is disposed on the die pad 332. The bonding wire 342 is selectively electrically connected to the die 341 and the connecting pattern 331.

Please note that the carrier 310 and the release film 320 can be easily removed form the pre-package structure 303 without jeopardizing other parts of the pre-package structure 303 because the release film 320 has a stronger adhesion to the carrier 310 and a weaker adhesion to the patterned copper film 330. In the meantime, the connecting pattern 331 and the die pad 332 together remain in the sealant material 343. After the carrier 310 and the release film 320 are removed form the pre-package structure 303, one side of both the connecting pattern 331 and the die pad 332 in the pre-package structure 305 is exposed.

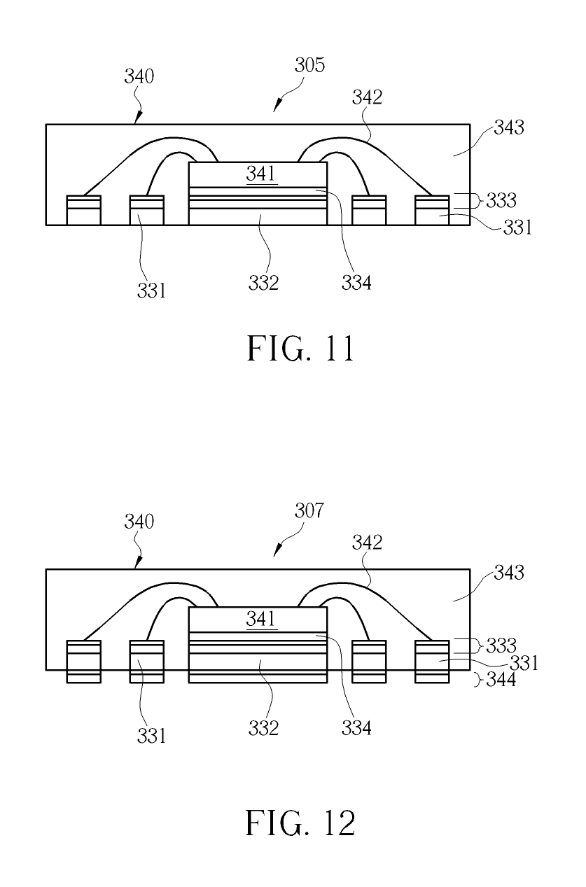

In order to protect the fragile copper film 330 of the connecting pattern 331 and the die pad 332, in still another embodiment of the present invention, a package structure 307 can be obtained after the pre-package structure 305 as illustrated in FIG. 11 further undergoes another protection step. FIG. 12 illustrates an extension method for making the package structure of the present invention. Please refer to the pre-package structure 305 in FIG. 11, a second passivation layer 344 may be formed on the connecting pattern 331 and the die pad 332 to completely cover the connecting pattern 331 and the die pad 332. The second passivation layer 344 may include at least one of Ni, Ag and Au by electroplating, to form a Ni/Au protective layer, or an organic solderability preservative (OSP) for instance.

After the aforesaid steps, a novel package structure 307 is obtained. Please refer to FIG. 12, illustrating the package structure 307 of the present invention. In the package structure 307 of the present invention, there are a connecting pattern 331, a die pad 332, a first passivation layer 333, a die 341, a bonding wire 342, a sealant material 343 and the second passivation layer 344. The connecting pattern 331, the die pad 332, the passivation layer 333, the die 341 and the bonding wire 342 are all disposed in the sealant material 343. The first passivation layer 333 covers the connecting pattern 331 and the die pad 332. The second passivation layer 344 is disposed outside the sealant material 343 and covers the connecting pattern 331 and the die pad 332 . The die 341 is disposed on the die pad 332. The bonding wire 342 is selectively electrically connected to the die 341 and the connecting pattern 331. Other features of the package structure 307 of the present invention, such as the package, may refer to the above descriptions and will not be repeated here.

Those skilled in the art will readily observe that numerous modifications and alterations of the device and method may be made while retaining the teachings of the invention.

What is claimed is:

1. A method for making a circuit board structure, comprising:
providing a substrate, comprising a carrier, a copper film and a release film which is disposed between said carrier and said copper film;
patterning said copper film to form a connecting pattern and a die pad; and
forming a first passivation to respectively cover said connecting pattern and said die pad to form said circuit board structure.

2. The method for making a circuit board structure of claim 1, wherein said substrate has a thickness of about 150 μm-400 μm.

3. The method for making a circuit board structure of claim 1, further comprising:
applying said release film onto said copper film; and
attaching said release film with said copper film onto said carrier to form said substrate.

4. The method for making a circuit board structure of claim 1, wherein applying said release film onto said copper film is carried out by at least one of a screen printing and a roller.

5. The method for making a circuit board structure of claim 1, further comprising:
applying said release film onto said carrier; and
attaching said release film with said carrier onto said copper film to form said substrate.

6. The method for making a circuit board structure of claim 1, wherein applying said release film onto said carrier is carried out by at least one of a screen printing and a roller.

7. The method for making a circuit board structure of claim 1, wherein said first passivation comprises at least one of Ni, Ag and Au.

8. The method for making a circuit board structure of claim 1, further comprising:
forming a package on said carrier.

9. The method for making a circuit board structure of claim 8, wherein said package comprises:
a die disposed on said die pad;
a bonding wire selectively electrically connecting said die and said connecting pattern; and
a sealant material hermetically sealing said die and said bonding wire and in direct contact with said release film.

10. The method for making a circuit board structure of claim 9, wherein said sealant material encloses said connecting pattern and said die pad.

11. The method for making a circuit board structure of claim 8, further comprising:
removing said release film and said carrier at the same time to expose said connecting pattern and said die pad.

12. The method for making a circuit board structure of claim 9, wherein said die is disposed among said connecting pattern.

13. The method for making a circuit board structure of claim 11, further comprising:
forming a second passivation to cover said connecting pattern and said die pad.

14. The method for making a circuit board structure of claim 13, wherein said second passivation comprises at least one of Ni, Ag and Au.

15. The method for making a circuit board structure of claim 13, wherein said second passivation comprises an organic solderability preservative (OSP).

16. A circuit board structure, comprising:
a carrier;
a release film attached to said carrier;
a connecting pattern disposed on said release film and in direct contact with said release film;
a die pad disposed on said release film; and
a passivation respectively covering said connecting pattern and said die pad.

17. A package structure, comprising:
a carrier;
a release film attached to said carrier;
a sealant material covering said release film;
a connecting pattern disposed in said sealant material;
a die pad disposed in said sealant material;
a passivation completely disposed in said sealant material and covering said connecting pattern and said die pad;
a die disposed on said die pad and completely disposed in said sealant material; and
a bonding wire completely disposed in said sealant material and selectively electrically connecting said die and said connecting pattern.

18. A package structure, comprising:
a sealant material;
a connecting pattern disposed in said sealant material;
a die pad disposed in said sealant material;
a passivation completely disposed in said sealant material and covering said connecting pattern and said die pad;
a die disposed on said die pad and completely disposed in said sealant material; and
a bonding wire completely disposed in said sealant material and selectively electrically connecting said die and said connecting pattern.

19. A package structure, comprising:
a sealant material;
a connecting pattern disposed in said sealant material;
a die pad disposed in said sealant material;
a first passivation completely disposed in said sealant material and covering said connecting pattern and said die pad;
a second passivation disposed outside said sealant material and covering said connecting pattern and said die pad;
a die disposed on said die pad and completely disposed in said sealant material; and
a bonding wire completely disposed in said sealant material and selectively electrically connecting said die and said connecting pattern.
